(19) United States
(12) Patent Application Publication
(10) Pub. No.: US 2026/0293460 A1
(43) Pub. Date: Sep. 24, 2026

(54) DISPLAY DEVICE

(71) Applicant: Sharp Display Technology Corporation, Kameyama City, Mie (JP)

(72) Inventor: Junichi YAMADA, Kameyama City (JP)

(21) Appl. No.: 19/473,350

(22) PCT Filed: Apr. 11, 2023
(86) PCT No.: PCT/JP2023/014672

§ 371 Date: Oct. 7, 2025

(51) Int. Cl. H10K 59/131; H10K 59/124

(52) U.S. Cl. CPC H10K 59/131; H10K 59/124

(57) ABSTRACT

A non-display portion of a display device according to the disclosure includes a trench extending through an organic insulating layer, and a plurality of wiring lines extending in a direction along the trench. A first wiring line closest to the trench among the plurality of wiring lines is located below the organic insulating layer and has a single-layer structure.

### TECHNICAL FIELD

The disclosure relates to a display device.

### BACKGROUND ART

PTL 1 discloses a configuration in which a structure (trench) extending through an organic film in a slit shape is disposed in a non-display portion (frame portion) for the purpose of preventing moisture from entering a display portion.

### CITATION LIST

### Patent Literature

PTL 1: WO 2019/224917 A1 (internationally published Nov. 28, 2019)

### SUMMARY

### Technical Problem

There is a demand for a reduction in the area of a non-display portion of a display device (frame narrowing).

### Solution to Problem

A display device according to an aspect of the disclosure includes a display portion including a plurality of light-emitting elements, and a non-display portion, the display portion and the non-display portion including an organic insulating layer, the non-display portion including a trench extending through the organic insulating layer and a plurality of wiring lines extending in a direction along the trench, and a first wiring line closest to the trench among the plurality of wiring lines being located below the organic insulating layer and having a single-layer structure.

### Advantageous Effects of Disclosure

According to the configuration of one aspect of the disclosure, a display device with a narrower frame can be provided.

### BRIEF DESCRIPTION OF DRAWINGS

FIG. 1 is a plan view illustrating a configuration example of a display device according to one embodiment of the disclosure.

FIG. 2 is a partial perspective plan view of the configuration example illustrated in FIG. 1.

FIG. 3 is a partial cross-sectional view of the configuration example illustrated in FIG. 1. FIG. 4 is a cross-sectional view illustrating a comparative example.

FIG. 5 is a plan view illustrating an example of a drive circuit and wiring line illustrated in FIG. 2.

FIG. 6 is a plan view illustrating an example of the drive circuit and wiring line illustrated in FIG. 2.

FIG. 7 is a partial cross-sectional view of a configuration example of a display device according to one embodiment of the disclosure.

### DESCRIPTION OF EMBODIMENTS

### First Embodiment

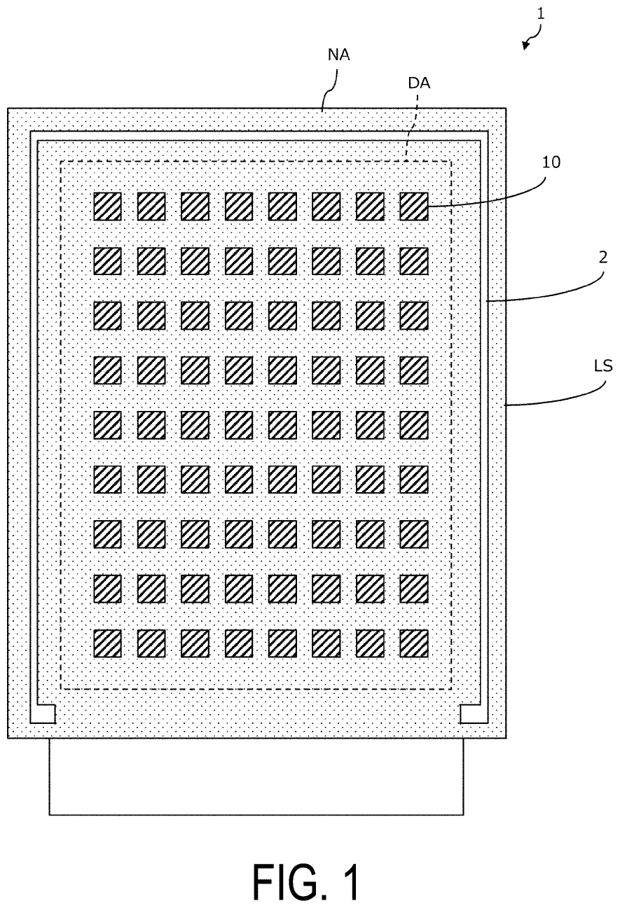

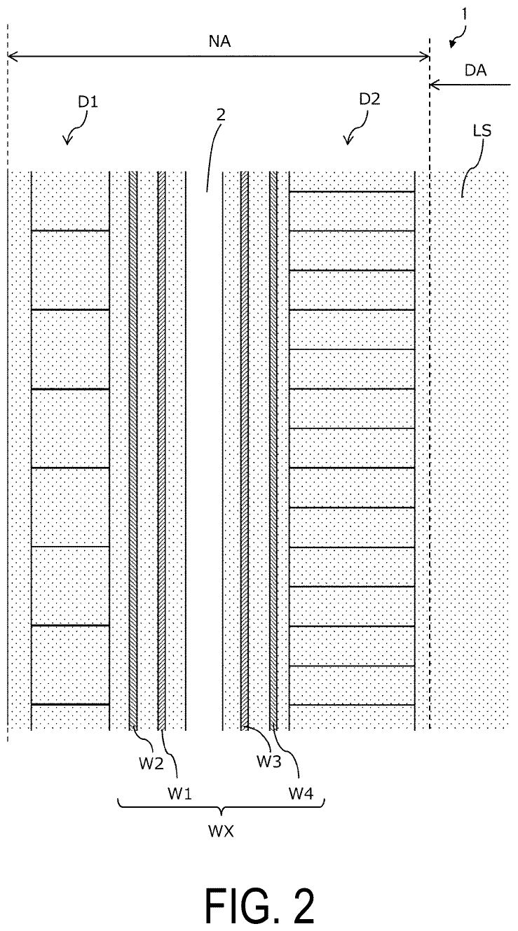

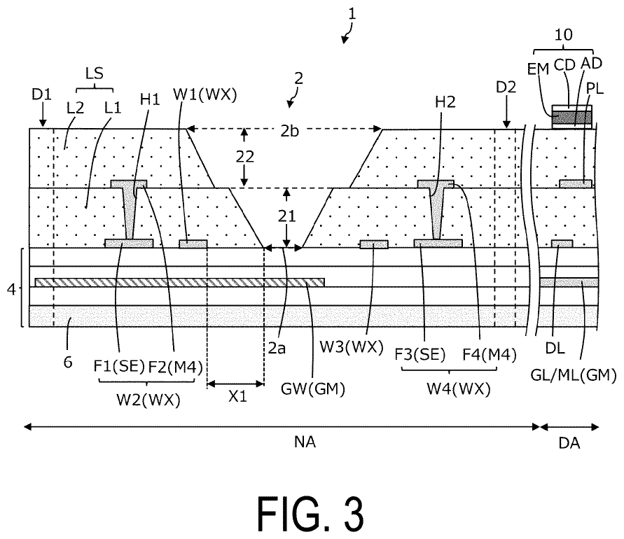

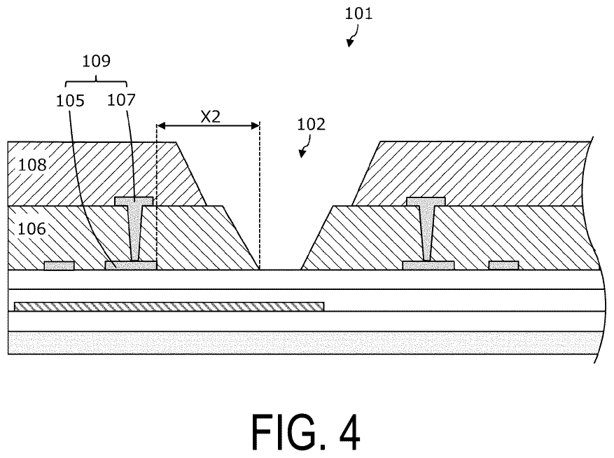

FIG. 1 is a plan view illustrating a configuration example of a display device according to one embodiment of the disclosure. FIG. 2 is a partial perspective plan view of the configuration example illustrated in FIG. 1. FIG. 3 is a partial cross-sectional view of the configuration example illustrated in FIG. 1. As illustrated in FIGS. 1 to 3, a display device 1 according to the disclosure includes a display portion DA including a plurality of light-emitting elements 10, and a non-display portion NA provided around the display portion DA. The display portion DA and the non-display portion NA each include an organic insulating layer LS, the non-display portion NA includes a trench 2 extending through the organic insulating layer LS and a plurality of wiring lines WX extending in a direction along the trench 2, and a first wiring line W1 closest to the trench 2 among the plurality of wiring lines WX is located below the organic insulating layer LS and has a single-layer structure.

The single-layer structure means a structure formed in a single metal layer not sandwiching an insulating layer, and a multilayer structure means a structure formed in a plurality of metal layers sandwiching an insulating layer with electrical connection. The single metal layer not sandwiching the insulating layer may be a metal layered film, and the first wiring line W1 may be a metal layered film (for example, a structure in which an aluminum film is sandwiched between two titanium films). The wiring line closest to the trench 2 may be the wiring line closest to the sidewall of the trench 2.

FIG. 4 is a cross-sectional view illustrating a comparative example. As illustrated in FIG. 4, in a display device 101 of the comparative example, a wiring line 109 closest to a trench 102 among a plurality of wiring lines extending in a direction along the trench 102 has a multilayer structure, and is formed by connecting a lower layer 105 located below an organic insulating layer 106 and an upper layer 107 located above the organic insulating layer 106. The upper layer 107 is covered with an organic insulating layer 108. The width and the cross-sectional shape of the trench 102 in FIG. 4 are the same as the width and the cross-sectional shape of the trench 2 in FIG. 3.

Although a clearance (margin distance) is required between the trench and the wiring line in consideration of insulating coating and manufacturing errors, in the present embodiment, the first wiring line W1 closest to the trench 2 has a single-layer structure, and thus a distance X1 between a bottom face 2a of the trench 2 and the first wiring line W1 can be made smaller than a distance X2 between the bottom face of the trench 102 and the lower layer 105 according to the comparative example. Therefore, frame narrowing of the display device 1 is possible. This is particularly preferable when the trench 2 becomes wider toward the upper side. The trench 2 can suppress a phenomenon in which water, oxygen, or the like enters the display portion DA through the organic insulating layer LS.

As illustrated in FIG. 3, the organic insulating layer LS may include a first organic insulating film L1 and a second organic insulating film L2 located above the first organic insulating film L1. The first wiring line W1 may be covered with the first organic insulating film L1.

The display device 1 may include an inorganic layer 4 located below the organic insulating layer LS and including a TFT (thin film transistor). The display portion DA and the non-display portion NA may include a metal layer GM included in the inorganic layer 4, a metal layer SE formed on the inorganic layer 4, and a metal layer M4 formed on the first organic insulating film L1, and the first wiring line W1 may be included in the metal layer SE, and a gate wiring line GW may be included in the metal layer GM.

The trench 2 may have a tapered shape that narrows downward (lower side in FIG. 3), and for example, the width of the bottom face 2a of the trench 2 may be ½ or less of an opening face 2b of the trench 2. The trench 2 includes a first portion 21 extending through the first organic insulating film L1 and a second portion 22 extending through the second organic insulating film L2, and the first portion 21 and the second portion 22 may not be aligned. For example, the upper face of the first portion 21 may be smaller than the lower face of the second portion 22, and the first portion 21 may be located inside the second portion 22 in a plan view. The opening face 2b of the trench 2 and the first wiring line W1 may overlap each other in a plan view. Only a part of the first wiring line W1 may overlap the opening face 2b, or the entire first wiring line W1 may overlap the opening face 2b.

The plurality of wiring lines WX extending in the direction along the trench 2 may include a second wiring line W2 having a multilayer structure, and the first wiring line W1 may be located between the second wiring line W2 and the trench 2. The second wiring line W2 may include a first layer F1 located in the same layer as the first wiring line W1 and a second layer F2 located on the first organic insulating film L1, and the first layer F1 and the second layer F2 may be connected to each other via a contact hole H1. The second layer F2 may be covered with the second organic insulating film L2.

The non-display portion NA may include a first drive circuit D1, and the first wiring line W1 and the second wiring line W2 may be located between the first drive circuit D1 and the trench 2. The non-display portion NA may include a second drive circuit D2, a third wiring line W3 having a single-layer structure, and a fourth wiring line W4 having a multilayer structure, and the third wiring line W3 and the fourth wiring line W4 may be located between the second drive circuit D2 and the trench 2. The third wiring line W3 may be located between the trench 2 and the fourth wiring line W4. The first drive circuit D1 and the second drive circuit D2 may drive the display portion DA.

The first wiring line W1 is closest to the trench 2 among the plurality of wiring lines WX extending between the trench 2 and the first drive circuit D1, and the third wiring line W3 is closest to the trench 2 among the plurality of wiring lines WX extending between the trench 2 and the second drive circuit D2. The third wiring line W3 is located below the organic insulating layer LS. A clearance is secured between the trench 2 and the third wiring line W3 in consideration of the insulating coating and manufacturing errors. The third wiring line W3 is covered with the first organic insulating film L1.

The fourth wiring line W4 includes a third layer F3 located in the same layer as the first wiring line W1 and a fourth layer F4 located on the first organic insulating film L1, and the third layer F3 and the fourth layer F4 are connected to each other via a contact hole H2. The fourth layer F4 may be located in the same layer as the second layer F2. The fourth layer F4 is covered with the second organic insulating film L2.

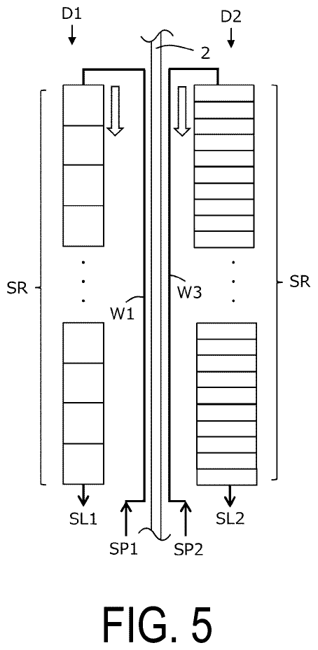

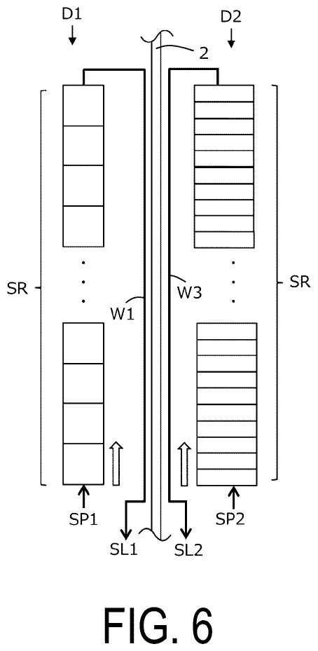

FIGS. 5 and 6 are plan views illustrating examples of the drive circuit and the wiring line illustrated in FIG. 2, respectively. As illustrated in FIGS. 5 and 6, the first drive circuit D1 includes a shift register SR, and the first wiring line W1 may transmit a start pulse signal SP1 to the shift register SR or an end pulse signal SL1 from the shift register SR. The second drive circuit D2 also includes the shift register SR, and the third wiring line W3 may transmit a start pulse signal SP2 to the shift register SR or an end pulse signal SL2 from the shift register SR. The start pulse signal wiring line and the end pulse signal wiring line may have a higher electrical resistivity per length than the clock signal wiring line and the power source wiring line.

The second wiring line W2 may supply clock signals or power supply to the first drive circuit D1. The fourth wiring line W4 may supply clock signals or power supply to the second drive circuit D2. The second wiring line W2 and the fourth wiring line W4 having the multilayer structure have a smaller electrical resistance per length than the first wiring line W1 and the third wiring line W3 having the single-layer structure.

The width of the first wiring line W1 may be smaller than the width of the first layer F1. The width of the first layer F1 may be larger than the width of the second layer F2. The first layer F1 and the second layer F2 may be formed of the same material. Similarly, the width of the third wiring line W3 may be smaller than the width of the third layer F3. The width of the third layer F3 may be larger than the width of the fourth layer F4.

The display portion DA and the non-display portion NA include the inorganic layer 4 including a thin film transistor, and the organic insulating layer LS is disposed on the inorganic layer 4. The plurality of wiring lines WX extending in the direction along the trench 2 are located above the inorganic layer 4. The first wiring line W1, the first layer F1, the third wiring line W3, and the third layer F3 may be located between the inorganic layer 4 and the organic insulating layer LS. The second layer F2 and the fourth layer F4 may be located inside the organic insulating layer LS. The inorganic layer 4 of the display portion DA may include a drive transistor that controls a current of each light-emitting element 10. The inorganic layer 4 may include a gate insulating film, a semiconductor layer, an interlayer insulating film, a wiring line, and an electrode, and may include the wiring line GW extending in a direction intersecting the trench 2.

In the display portion DA, the light-emitting element 10 is provided on the organic insulating layer LS. In the display portion DA, an anode AD of each light-emitting element 10 is located on the second organic insulating film L2. A light-emitting layer EM and a cathode CD may be located on the anode AD.

The display portion DA includes a data signal line DL, and the data signal line DL may be located on the same layer as the first wiring line W1 or on the first organic insulating film L1. The display portion DA includes a power source wiring line PL, and the power source wiring line PL may be located on the first organic insulating film L1 or in the same layer as the first wiring line W1. For example, the data signal line may be located in the same layer as the first wiring line W1, and the power source wiring line PL may be located on the first organic insulating film L1. The display portion DA may include a scanning signal line GL and a light emission control line ML. The scanning signal line GL and the light emission control line ML may be located inside the inorganic layer 4.

The first drive circuit D1 may be a scan driver connected to the scanning signal line GL or an emission driver connected to the light emission control line ML. The second drive circuit D2 may also be an emission driver or a scan driver. For example, the first drive circuit D1 may be an emission driver, and the second drive circuit D2 may be a scan driver.

### Second Embodiment

Another embodiment of the disclosure will be described below. Further, members having the same functions as those of the members described in the above-described embodiment will be denoted by the same reference numerals and signs, and a description thereof will not be repeated for convenience of description.

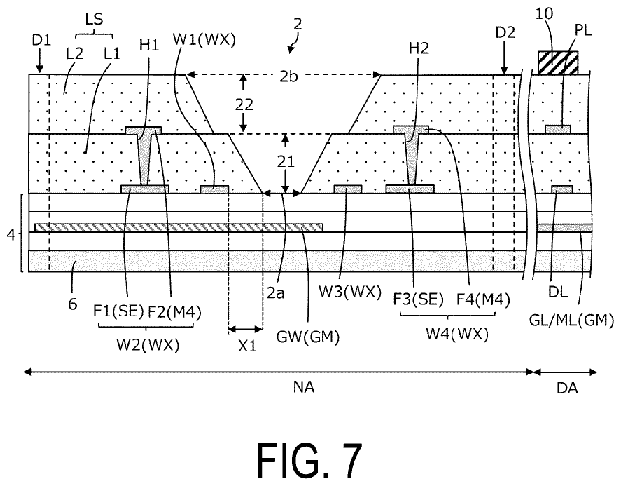

FIG. 7 is a partial cross-sectional view of a configuration example of a display device according to one embodiment of the disclosure. As illustrated in FIG. 7, the lower face of the second portion 22 of the trench 2 and the first wiring line W1 may overlap each other in a plan view. Only a portion of the first wiring line W1 may overlap the lower face of the second portion 22, or the entire first wiring line W1 may overlap the lower face of the second portion 22.

Similarly, the third wiring line W3 may overlap the lower face of the second portion 22.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A display device comprising:
a display portion including a plurality of light-emitting elements; and
a non-display portion,
wherein the display portion and the non-display portion include an organic insulating layer,
the non-display portion includes a trench extending through the organic insulating layer and a plurality of wiring lines extending in a direction along the trench, and
a first wiring line closest to the trench among the plurality of wiring lines is located below the organic insulating layer and has a single-layer structure,
the trench has a tapered shape narrowing downward, and
an opening face of the trench and the first wiring line overlap each other in a plan view.

2. The display device according to claim 1,
wherein the organic insulating layer includes a first organic insulating film and a second organic insulating film located above the first organic insulating film.

3. The display device according to claim 2,
wherein the first wiring line is covered with the first organic insulating film.

4-5. (canceled)

6. A display device comprising:
a display portion including a plurality of light-emitting elements; and
a non-display portion,
wherein the display portion and the non-display portion include an organic insulating layer,
the non-display portion includes a trench extending through the organic insulating layer and a plurality of wiring lines extending in a direction along the trench,
a first wiring line closest to the trench among the plurality of wiring lines is located below the organic insulating layer and has a single-layer structure,
the organic insulating layer includes a first organic insulating film and a second organic insulating film located above the first organic insulating film,
the plurality of wiring lines include a second wiring line having a multilayer structure, and
the first wiring line is located between the second wiring line and the trench.

7. The display device according to claim 6,
wherein the second wiring line includes a first layer located in the same layer as the first wiring line and a second layer located on the first organic insulating film, and
the first layer and the second layer are connected to each other via a contact hole.

8. The display device according to claim 6-or 7,
wherein the non-display portion includes a first drive circuit, and
the first wiring line and the second wiring line are located between the first drive circuit and the trench.

9. The display device according to claim 8,
wherein the non-display portion includes a second drive circuit, a third wiring line having a single-layer structure, and a fourth wiring line having a multilayer structure, and
the third wiring line and the fourth wiring line are located between the second drive circuit and the trench.

10. The display device according to claim 9,
wherein the third wiring line is located between the trench and the fourth wiring line.

11. The display device according to claim 8,
wherein the first drive circuit includes a shift register, and
the first wiring line transmits a start pulse signal to the shift register or an end pulse signal from the shift register.

12. The display device according to claim 8,
wherein the second wiring line supplies a clock signal or power supply to the first drive circuit.

13. The display device according to claim 7,
wherein a width of the first wiring line is smaller than a width of the first layer.

14. The display device according to claim 7,
wherein a width of the first layer is larger than a width of the second layer.

15. The display device according to claim 7,
wherein the first layer and the second layer are formed from the same material.

16-23. (canceled)

24. The display device according to claim 8,
wherein the display portion includes a scanning signal line and a light emission control line.

25. The display device according to claim 24,
wherein the first drive circuit is a scan driver connected to the scanning signal line or an emission driver connected to the light emission control line.
